(19) United States
(12) Patent Application Publication
(10) Pub. No.: US 2025/0194010 A1
(43) Pub. Date: Jun. 12, 2025

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventor: Jun Ki Min, Suwon-si (KR)

(73) Assignee: SAMSUNG ELECTRO-MECHANICS CO., LTD., Suwon-si (KR)

(21) Appl. No.: 18/883,538

(22) Filed: Sep. 12, 2024

(30) Foreign Application Priority Data
Dec. 8, 2023 (KR) 10-2023-0177911

(51) Int. Cl. H05K 1/11; H05K 1/02; H05K 3/40

(52) U.S. Cl. CPC H05K 1/115; H05K 1/0298; H05K 3/4038; H05K 2201/096; H05K 2201/09827; H05K 2201/2081

(57) ABSTRACT

A printed circuit board includes a first insulating layer; a first wiring layer buried in the first insulating layer; a first solder resist layer located on the first insulating layer; and a cavity formed along a height direction, penetrating through the first solder resist layer, and penetrating through a portion of the first insulating layer, in which a second depth of an edge portion of the cavity may be greater than a first depth of a central portion of the cavity along the height direction.

### CROSS-REFERENCE TO RELATED APPLICATION

This application claims priority to and the benefit of Korean Patent Application No. 10-2023-0177911 filed in the Korean Intellectual Property Office on Dec. 8, 2023, the entire contents of which are incorporated herein by reference.

### BACKGROUND

### 1. Field

The present disclosure relates to a printed circuit board and a manufacturing method thereof.

### 2. Description of the Related Art

A printed circuit board has a circuit pattern formed with a conductive material, such as copper, on an insulating material. A method of forming a cavity in a printed circuit board as electronic devices in the IT field including mobile phones become smaller and mounting electronic components, such as ICs, active elements, or passive elements, within the cavity has been proposed.

The deeper the cavity of the printed circuit board, the more parts of the electronic components can be mounted within the cavity. The wider the cavity, the larger the bonding surface area between a molding material that fills the cavity and fixes the electronic components and the cavity, so it is possible to increase adhesion of the molding material when the molding material is injected, it is possible to easily move the molding material and prevent voids, etc., from occurring.

However, when the cavity is made wider, an area occupied by wiring formed within the printed circuit board may become narrow.

### SUMMARY

The present disclosure attempts to provide a printed circuit board including a cavity that has a sufficient area in which electronic components may be mounted and may improve molding characteristics by increasing a bonding surface area between a molding material and a cavity, and a manufacturing method thereof.

However, problems to be solved by the embodiments are not limited to the above-described problems and may be variously extended in the range of technical ideas included in the embodiments.

According to some embodiments of the present disclosure, a printed circuit board may include a first insulating layer; a first wiring layer buried in the first insulating layer; a first solder resist layer located on the first insulating layer; and a cavity penetrating through the first solder resist layer and penetrating in a portion of the first insulating layer along a height direction, in which a first depth of a central portion of the cavity may be less than a second depth of an edge portion of the cavity along the height direction.

The cavity may include a first part in the portion of the first insulating layer, a second part in the edge portion of the cavity, and a third part in the first solder resist layer.

A portion where the side wall and a bottom surface of the second part of the cavity meet may have a rounded shape.

A side wall of the first part and a side wall of the second part may be aligned with each other along the height direction.

A first width of the first part, a second width of the second part, and a third width of the third part may be different from each other along a plane direction perpendicular to the height direction.

The second width of the second part may be less than the first width of the first part and the third width of the third part.

The third width of the third part may be greater than the first width of the first part.

The printed circuit board may further include a first via located in a first via hole within the first insulating layer and connected to the first wiring layer, in which the first depth of the first part may be substantially equal to a first thickness of the first wiring layer, and the second depth of the second part may be less than a second thickness of the first via.

The third depth of the third part may be substantially equal to a third thickness of the first solder resist layer.

According to another embodiments of the present disclosure, a manufacturing method of a printed circuit board may include: forming a first wiring layer and a first sacrificial layer; stacking a first insulating layer burying the first wiring layer and the first sacrificial layer on the first wiring layer and the first sacrificial layer; forming a first via hole overlapping a first wiring layer in the first insulating layer; forming a first via in the first via hole of the first insulating layer; forming a preliminary cavity by removing the first sacrificial layer by a first etching; and removing an edge portion of a bottom portion of the preliminary cavity by a second etching to form a cavity in which a first depth of a central portion may be less than a second depth of an edge portion along a height direction.

The manufacturing method may further include forming a solder resist layer having an opening exposing the preliminary cavity on the first insulating layer.

According to some embodiments of the present disclosure, it is possible to provide a printed circuit board including a cavity that has a sufficient area in which electronic components may be mounted and may improve molding characteristics by increasing a bonding surface area between a molding material and the cavity, and a manufacturing method thereof.

However, it is obvious that the effects of the embodiments are not limited to the above-described effects, and may be variously extended without departing from the spirit and scope of this disclosure.

### BRIEF DESCRIPTION OF THE DRAWINGS

FIG. 1 is a cross-sectional view of a printed circuit board according to an embodiment.

FIG. 2 is an enlarged view of a portion of the printed circuit board according to an embodiment.

FIGS. 3 to 13 are cross-sectional views illustrating a manufacturing method of a printed circuit board according to an embodiment.

FIG. 14 is a schematic cross-sectional view of a semiconductor device including the printed circuit board according to the embodiment.

### DETAILED DESCRIPTION

Hereinafter, some embodiments of the present disclosure will be described in detail with reference to the accompanying drawings so that those skilled in the art to which this disclosure pertains may easily practice this disclosure. However, this disclosure may be implemented in various different forms and is not limited to embodiments provided herein.

Portions unrelated to the description will be omitted in order to obviously describe some embodiments of this disclosure, and similar components will be denoted by the same reference numerals throughout the present specification.

Further, it should be understood that the accompanying drawings are provided only in order to allow embodiments of the present disclosure to be easily understood, and the spirit of the present disclosure is not limited by the accompanying drawings, but includes all the modifications, equivalents, and substitutions included in the spirit and the scope of the present disclosure.

In addition, the size and thickness of each component illustrated in the drawings are arbitrarily indicated for convenience of description, and this disclosure is not necessarily limited to the illustrated those. In the drawings, the thickness of layers, films, panels, regions, etc., are exaggerated for clarity. In addition, in the accompanying drawings, thicknesses of some of layers and regions have been exaggerated for convenience of explanation.

In addition, It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, when an element is referred to as being “on” a reference element, it can be positioned on or beneath the reference element, and is not necessarily positioned on the reference element in an opposite direction to gravity.

In addition, unless explicitly described to the contrary, the word “comprise”, and variations such as “comprises” or “comprising”, will be understood to imply the inclusion of stated elements but not the exclusion of any other elements.

Further, throughout the specification, the word “plan view” refers to a view when a target is viewed from the top, and the word “cross-sectional view” refers to a view when a cross section of a target taken along a vertical direction is viewed from the side.

Also, throughout the specification, when it is said to be “connected,” this does not mean that two or more components are directly connected, but means that two or more components are indirectly connected through another component, that two or more components are physically connected as well as electrically connected, or that two or more components are referred to by different names depending on their location or function, but are integral.

Hereinafter, various embodiments and modifications will be described in detail with reference to the drawings.

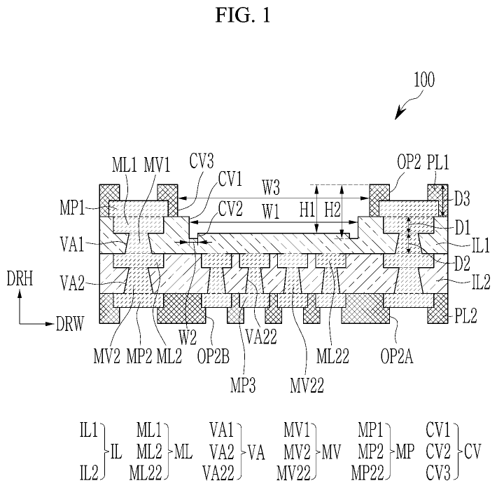

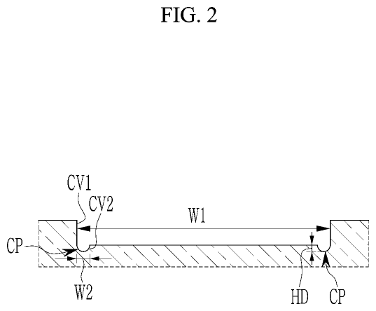

Referring to FIGS. 1 and 2, a printed circuit board according to an embodiment will be described. FIG. 1 is a cross-sectional view of a printed circuit board according to an embodiment. FIG. 2 is an enlarged view of a portion of the printed circuit board according to an embodiment.

Referring to FIG. 1, a printed circuit board 100 according to the present embodiment may include: a plurality of stacked insulating layers IL, a plurality of vias MV located within a plurality of via holes VA of a plurality of wiring layers ML buried in the plurality of insulating layers IL, a plurality of pad parts MP, a solder resist layer PL, and a cavity CV formed in a portion of the plurality of insulating layers IL.

The plurality of insulating layers IL may include a first insulating layer IL1 and a second insulating layer IL2 located below the first insulating layer IL1 along a height direction DRH.

The plurality of wiring layers ML may include a first wiring layer ML1 buried by the first insulating layer IL1, and a second wiring layer ML2 and a third wiring layer ML22 buried by the second insulating layer IL2.

The plurality of vias MV may include a first via MV1 located in a first via hole VA1 formed in the first insulating layer IL1, a second via MV2 located in a second via hole VA2 formed in the second insulating layer IL2, and a third via MV22 located in a third via hole VA22 formed in the second insulating layer IL2.

The plurality of pad layers MP may include a first pad layer MP1 located on the first insulating layer IL1, a second pad layer MP2 and a third pad layer MP3 located below the second insulating layer IL2.

A portion of the first wiring layer ML1 and a portion of the second wiring layer ML2 may be connected through the first via MV1, a portion of the second wiring layer ML2 and the second pad layer MP2 may be connected through the second via MV2, the first pad layer MP1 may be connected to the first wiring layer ML1, and a portion of the third wiring layer ML22 and the third pad layer MP3 may be connected to each other through the third via MV22.

The solder resist layer PL may include a first solder resist layer PL1 located on the first insulating layer IL1 and exposing a portion of the first pad layer MP1 through an opening OP2, and a second solder resist layer PL2 located below the second insulating layer IL2 and exposing portions of the second pad layer MP2 and the third pad layer MP3 through openings OP3A and OP3B.

The cavity CV may include a first part CV1 and a second part CV2 formed in the first insulating layer IL1 and having different widths and heights, and a third part CV3 formed in the first solder resist layer PL1.

The first part CV1 of the cavity CV is located at a side surface of the first wiring layer ML1, the second part CV2 of the cavity CV is located at a side surface of the first via MV1, and the cavity CV of the third part CV3 is located at a side surface of the first solder resist layer PL1.

Along the height direction DRH, the first part CV1 of the cavity CV may be located on the second part CV2 of the cavity CV, and the third part CV3 of the cavity may be located on the first part CV1 of the cavity CV.

Along a plane direction DRW perpendicular to the height direction DRH, the second part CV2 of the cavity CV may be located at an edge of a bottom surface of the cavity CV.

Along the height direction DRH, the first part CV1 of the cavity CV may have a depth substantially equal to a first thickness D1 of the first wiring layer ML1 buried by the first insulating layer IL1, the second part CV2 of the cavity CV may have a depth smaller than a second thickness D2 of the first via MV1 located in the first via hole VA1 formed in the first insulating layer IL1, and the third part CV3 of the cavity CV may have a depth substantially equal to a third thickness D3 of the first solder resist layer PL1.

Along the height direction DRH, a central portion of the cavity CV may include the first part CV1 and the third part CV3, the central portion of the cavity CV may have a first depth H1, which may be a total depth of D1 and D3. The edge portion of the cavity CV may further include the second part CV2 in addition to the first part CV1 and the third part CV3, and the edge portion of the cavity CV may have a second depth H2, which may be a total depth of D1, D2 and D3. The second depth H2 may be greater than the first depth H1.

Referring to FIGS. 1 and 2, as described above, along the height direction DRH, the central portion of the cavity CV may include the first part CV1 and the third part CV3, the central portion of the cavity CV may have the first depth H1, the edge portion of the cavity CV may further include the second part CV2 in addition to the first part CV1 and the third part CV3, and the edge portion of the cavity CV may have the second depth H2. The second depth H2 may be greater than the first depth H1. Accordingly, the bottom surface of the central portion of the cavity CV and the bottom surface of the edge portion of the cavity CV may have a height difference HD.

Along the plane direction DRW perpendicular to the height direction DRH, the first part CV1 of the cavity CV formed in the first insulating layer IL1 may have a first width W1, the second part CV2 of the cavity CV formed in the first insulating layer IL1 may have a second width W2, and the third part CV3 of the cavity CV formed in a portion of the first solder resist layer PL1 may have a third width W3.

The first width W1 of the first part CV1 of the cavity CV may be different from the second width W2 of the second part CV2 of the cavity CV. The first width W1 of the first part CV1 of the cavity CV may be greater than the second width W2 of the second part CV2 of the cavity CV.

The second part CV2 of the cavity CV may overlap the first part CV1 of the cavity CV along the height direction DRH.

The third width W3 of the third part CV3 of the cavity CV may be greater than the first width W1 of the first part CV1 of the cavity CV.

The side walls of the first part CV1 and the second part CV2 of the cavity CV may be aligned along the height direction DRH.

The printed circuit board according to some embodiments of the present disclosure may further include the second portion CV2 of the cavity CV that is formed in a portion of the first insulating layer IL1 and the second solder resist layer PL2, is located at an edge of the bottom portion of the cavity CV, and has a depth greater than that of the first part CV1 of the cavity CV, thereby maintaining the sufficient bottom surface on which the electronic components may be mounted and increasing the surface area of the bottom portion of the cavity CV. Therefore, during the manufacturing process, it is possible to improve molding characteristics by increasing a bonding surface area between the molding material inserted into the cavity CV and the cavity, and it is easy to move the molding material to the edge portion of the cavity when the molding material is injected and it is possible to prevent voids, etc., from occurring.

Referring to FIG. 2, according to some embodiments of the present disclosure, the bottom portion of the second part CV2 of the cavity located at the edge portion of the bottom surface of the cavity CV may include a corner portion CP having a curved and rounded shape at a portion connected to the side wall of the cavity CV. When the corner portion where the side wall and the bottom portion of the cavity (CV) meet has a bent form, the molding material does not fill the corner portion of the cavity when the molding material is injected into the cavity, so defects such as voids may be caused. However, according to some embodiments of the present disclosure, the corner portion CP where the bottom surface and the side wall of the second portion CV2 of the cavity located at the edge portion of the bottom surface of the cavity CV meet has the curved and rounded shape, so the molding material may well fill the corner portion, thereby preventing the defects such as voids from occurring.

In the illustrated embodiment, the first part CV1 of the cavity CV is located in a portion of the first insulating layer IL1, but according to another embodiment, the first part CV1 of the cavity CV may be formed within an additional insulating layer in addition to the insulating layer IL1.

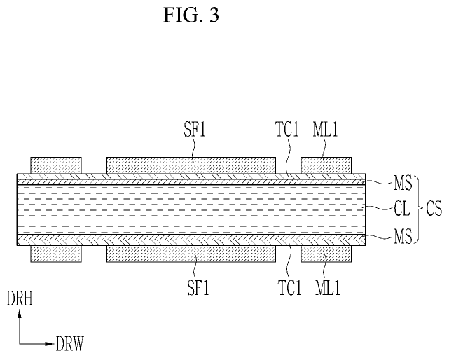

A manufacturing method of a printed circuit board according to some embodiments will be described with reference to FIGS. 3 to 13 along with FIG. 1. FIGS. 3 to 13 are cross-sectional views illustrating a manufacturing method of a printed circuit board according to an embodiment.

Referring to FIG. 3, a first copper foil layer TC1 and a first wiring layer ML1 may be formed on a carrier substrate CS including a core portion CL and a thin metal layer MS stacked on both sides of the core portion CL. In this case, a first sacrificial layer SF1 disposed at the location where the cavity CV is to be formed may be formed together. Since the first sacrificial layer SF1 is formed together with the first wiring layer ML1, the first sacrificial layer SF1 may be made of the same material as the first wiring layer ML1 and has a thickness substantially equal to the first thickness D1 of the first wiring layer ML1.

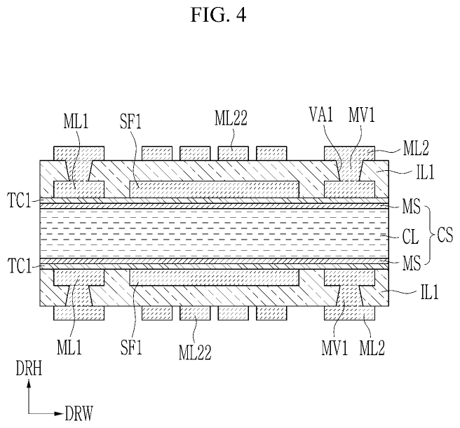

As illustrated in FIG. 4, the first insulating layer IL1 may be formed on the first wiring layer ML1 and the first sacrificial layer SF1 to bury the first wiring layer ML1 and the first sacrificial layer SF1 with the first insulating layer IL1, the first via hole VA1 that overlaps with the first wiring layer ML1 may be formed in the first insulating layer IL1, the first via MV1 located within first via hole VA1 may be formed, the second wiring layer ML2 that overlaps with the first via MV1 may be formed on the first insulating layer IL1, and the third wiring layer ML22 may be formed on the first insulating layer IL1.

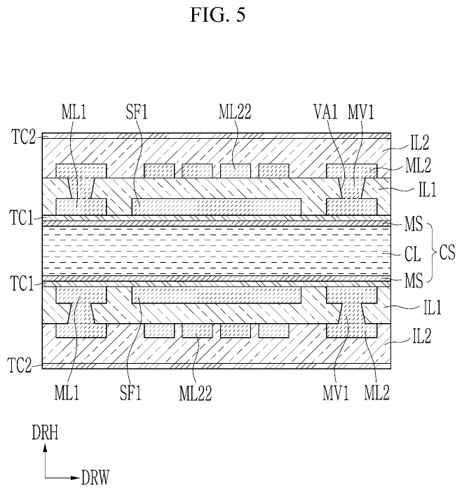

Referring to FIG. 5, the second insulating layer IL2 and a second copper foil layer TC2 are formed on the second wiring layer ML2 and the third wiring layer ML22, so that the second wiring layer ML2 and the third wiring layer ML22 are buried in the second insulating layer IL2.

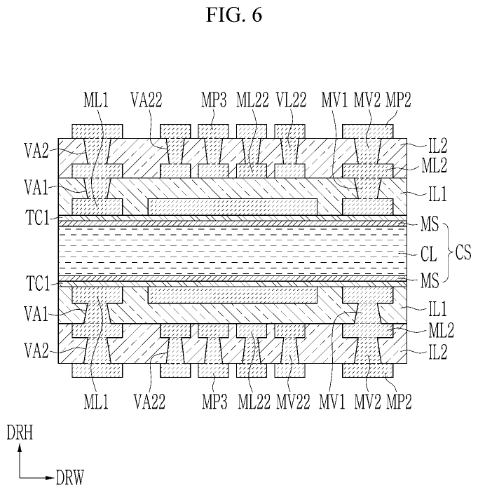

Referring to FIG. 6, the second via hole VA2 overlapping the second wiring layer ML2 and the third via hole VA22 overlapping the third wiring layer ML22 may be formed in the second insulating layer IL2, a second via VL2 may be formed within second via hole VA2 and a third via VL22 may be formed within the third via hole VA22, and the second pad layer MP2 connected to the second wiring layer ML2 through the second via VL2 and the third pad layer MP3 connected to the third wiring layer ML22 through the third via VL22 may be formed on the second insulating layer IL2.

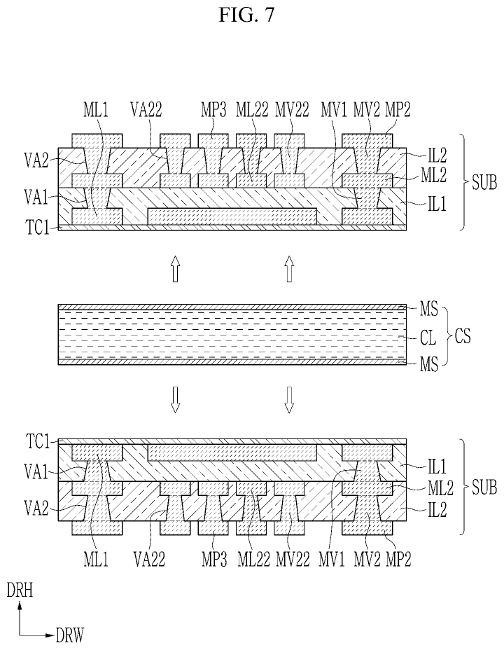

Next, as illustrated in FIG. 7, a substrate portion SUB is peeled from both sides of the carrier substrate CS.

Hereinafter, one substrate part SUB peeled from the carrier substrate CS will be described.

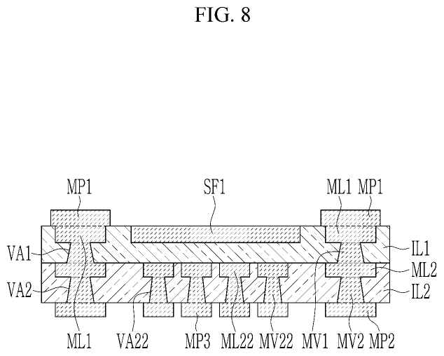

As illustrated in FIG. 8, the first copper foil layer TC1 is removed from the substrate portion SUB, and the first pad layer MP1 is formed on the first wiring layer ML1.

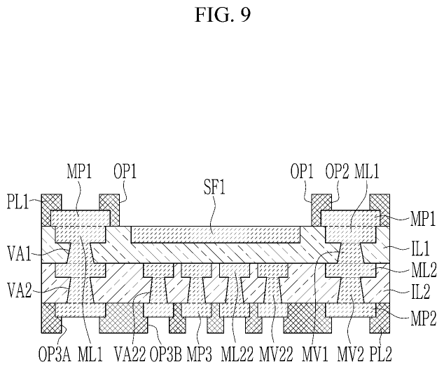

Referring to FIG. 9, the first solder resist layer PL1 is formed on the first insulating layer IL1, and the second solder resist layer PL2 is formed under the second insulating layer IL2.

The first solder resist layer PL1 may include a first opening OP1 completely exposing the first sacrificial layer SF1 and a second opening OP2 overlapping at least a portion of the first pad layer MP1, and the second solder resist layer PL2 may have a third opening OP3A overlapping the second pad layer MP2 and a fourth opening OP3B overlapping the third pad layer MP3.

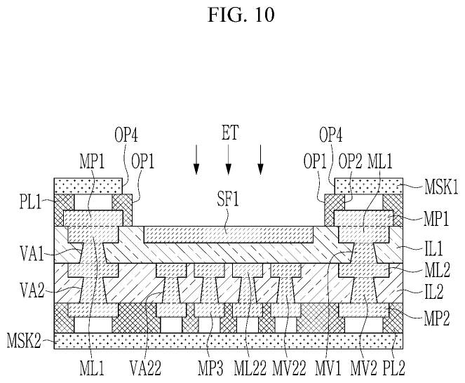

As illustrated in FIG. 10, a first mask layer MSK1 covering the second opening OP2 of the first solder resist layer PL1 and exposing the first opening OP1 is disposed on the first solder resist layer PL1, and a second mask layer MSK2 is disposed below the second solder resist layer PL2 to cover the third opening OP3A and the fourth opening OP3B. All parts except an area where the cavity CV is to be formed may be covered by the first mask layer MSK1 and the second mask layer MSK2.

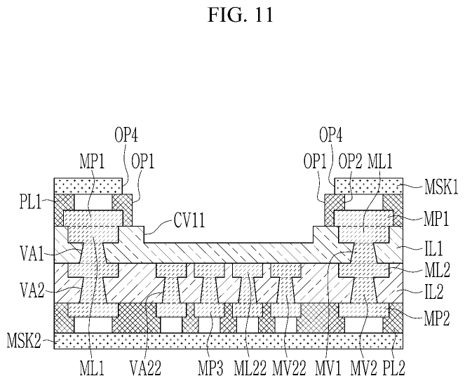

Using the first mask layer MSK1 and the second mask layer MSK2 as an etch mask, the first sacrificial layer SF1 located in the area where the cavity CV is to be formed may be subjected to first etching ET, so, as illustrated in FIG. 11, a preliminary cavity CV11 may be formed in a portion where the first sacrificial layer SF1 is located.

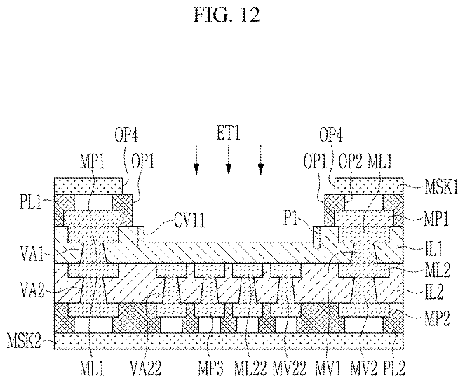

Referring to FIG. 12, using the first mask layer MSK1 and the second mask layer MSK2 as the etch mask, a side wall and a portion P1 of a bottom portion of the preliminary cavity CV11 located at the edge portion of the preliminary cavity CV11 may be removed by second etching ET1. The second etching ET1 may use a laser, but the embodiment is not limited thereto.

In FIG. 12, the side wall and the portion P1 of the bottom portion of the preliminary cavity CV11 located at the edge portion of the preliminary cavity CV11 to be removed through the second etching ET1 is indicated by an approximately quadrangular dotted line.

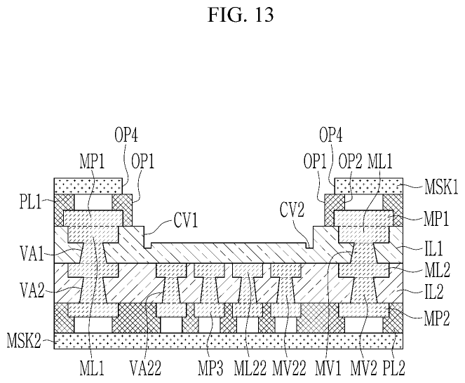

By removing the side wall and the portion P1 of the bottom portion of the preliminary cavity CV11 located at the edge portion of the preliminary cavity CV11 through the second etching ET1, as illustrated in FIG. 13, the first part CV1 of the cavity CV located at the side surface of the first wiring layer ML1 and the second part CV2 of the cavity CV located at the side surface of the first via MV1 may be formed.

As previously described with reference to FIG. 2, according to an embodiment, the corner portion CP where the bottom surface and the side wall of the second part CV2 of the cavity meet may be formed to have a curved, rounded shape.

The first opening OP1 completely exposing the first sacrificial layer SF1 of the first solder resist layer PL1 may be the third part CV3 of the cavity CV.

Thereafter, the first mask layer MSK1 and the second mask layer MSK2 may be removed to form the printed circuit board 100 of FIG. 1.

According to the method of manufacturing a printed circuit board according to the present embodiment, by forming a plurality of dummy patterns DP and first sacrificial layer SF1 to be buried in the first insulating layer IL1, removing the first sacrificial layer SF1 by the first etching ET using the mask layers MSK1 and MSK2 as etching masks, and forming the second part CV2 of the cavity CV by removing the side wall and the portion of the bottom portion of the edge portion of the cavity CV of the first insulating layer IL1 by the second etching ET1, the cavity CV may be formed to have a wider width and deeper depth than the preliminary cavity CV11. Therefore, by maintaining the sufficient bottom surface on which the electronic components may be mounted and increasing the surface area of the bottom portion of the cavity CV, when the semiconductor device is formed by mounting the electronic components on the printed circuit board, it is possible to improve the molding characteristics by increasing the bonding surface area between the molding material inserted into the cavity CV and the cavity, and when injecting the molding material, it may be easy to move to the edge portion of the cavity of the molding material and prevent voids from occurring.

In addition, according to some embodiments of the present disclosure, the corner portion CP where the bottom surface and the side wall of the second part CV2 of the cavity CV located at the edge portion of the bottom surface of the cavity CV meet may be formed to have the curved and rounded shape. The corner portion where the bottom surface and the side wall meet is formed to have the curved and rounded shape, so the molding material may well fill the corner portion, there preventing the defects such as voids from occurring.

In the illustrated embodiment, the first sacrificial layer SF1 formed at the location where the preliminary cavity CV11 of the cavity CV is to be formed is formed to be located within at least a portion of the first insulating layer IL1, but according to another embodiment, the first sacrificial layer SF1 formed at the location where the preliminary cavity CV11 is to be formed may be additionally formed within an additional insulating layer. In this case, the depth of the first part CV1 of the cavity CV may become greater.

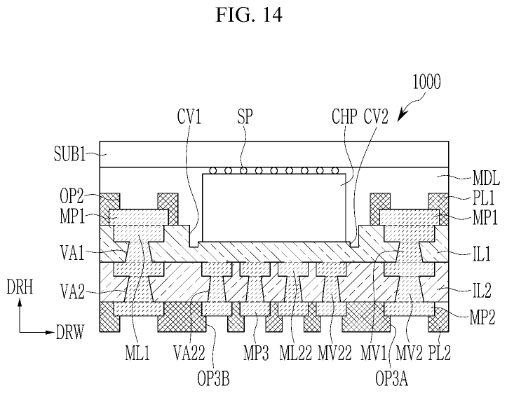

A semiconductor device including a printed circuit board according to some embodiments will be described with reference to FIG. 14. FIG. 14 is a schematic cross-sectional view of a semiconductor device including the printed circuit board according to the embodiment.

Referring to FIG. 14, a semiconductor device 1000 according to some embodiments may include the printed circuit board 100 according to the embodiment previously described with reference to FIG. 1 to FIG. 3, an opposite substrate SUB1 that faces the printed circuit board 100, a mounting chip CHP for electronic components, which is located within the cavity CV of the printed circuit board 100 and electrically connected to the opposite substrate SUB1 through a connection part SP, and a molding layer MDL that is located between the printed circuit board 100 and the opposite substrate SUB1 and connects the printed circuit board 100 and the opposite substrate SUB1 to each other.

According to the semiconductor device 1000 according to the present embodiment, the cavity CV of the printed circuit board 100 where the mounting chip CHP is located may further include the second part CV2 of the cavity CV, that is formed on a portion of the first insulating layer IL1 and the second solder resist layer PL2, located at the edge of the bottom portion of the cavity CV, and has a deeper depth than the first part CV1 of the cavity CV, thereby maintaining the sufficient bottom surface on which electronic components may be mounted and increasing the surface area of the bottom portion of the cavity CV. Therefore, during the manufacturing process, it is possible to improve the molding characteristics by increasing the bonding surface area between the molding material inserted into the cavity CV and forming the molding layer MDL and the cavity, and it is easy to move the molding material to the edge portion of the cavity when the molding material is injected and it is possible to prevent voids, etc., from occurring.

In addition, according to the embodiment, the corner portion CP where the bottom surface and the side wall of the second part CV2 of the cavity CV located at the edge portion of the bottom surface of the cavity CV meet may be formed to have the curved and rounded shape, so the molding material may well fill the corner portion, thereby preventing the defects such as voids from occurring.

Many features of the printed circuit board 100 and the manufacturing method of the printed circuit board according to the embodiments described above are all applicable to the semiconductor device 1000 according to the present embodiment.

Although preferred embodiments have been described above, this disclosure is not limited thereto, and this disclosure can be variously modified within the scope of the claims, the detailed description of this disclosure, and the appended drawings, and it is natural that various modifications also fall within the scope of this disclosure.

### DESCRIPTION OF SYMBOLS

CV, CV1, CV2, CV3: Cavity
IL, IL1, IL2: Insulating layer
ML, ML1, ML2, ML22: Wiring layer
MP, MP1, MP2, MP3: Pad layer
VA, VA1, VA2, VA22: Via hole
MV, MV1, MV2, MV22: Via
PL, PL1, PL2: Solder resist layer
SF1: Sacrificial layer
MSK1, MSK2: Mask layer

What is claimed is:

1. A printed circuit board, comprising:
a first insulating layer;
a first wiring layer buried in the first insulating layer;
a first solder resist layer located on the first insulating layer; and
a cavity penetrating through the first solder resist layer and a portion of the first insulating layer along a height direction,
wherein a depth of a central portion of the cavity is less than a depth of an edge portion of the cavity along the height direction.

2. The printed circuit board of claim 1, wherein:
the cavity includes a first part in the portion of the first insulating layer, a second part in the edge portion of the cavity, and a third part in the first solder resist layer, and
a side wall of the first part and a side wall of the second part are aligned with each other along the height direction.

3. The printed circuit board of claim 2, wherein
a bottom surface of the second part of the cavity has a rounded shape.

4. The printed circuit board of claim 2, wherein
a width of the first part, a width of the second part, and a width of the third part are different from each other along a plane direction perpendicular to the height direction.

5. The printed circuit board of claim 4, wherein
the width of the second part is less than the width of the first part and the width of the third part.

6. The printed circuit board of claim 5, wherein
the width of the third part is greater than the width of the first part.

7. The printed circuit board of claim 6, further comprising:
a first via located in a first via hole within the first insulating layer and connected to the first wiring layer,
wherein the depth of the central portion of the cavity is substantially equal to a first thickness of the first wiring layer, and
the depth of edge portion of the cavity is less than a second thickness of the first via.

8. The printed circuit board of claim 7, wherein
a depth of the third part is substantially equal to a third thickness of the first solder resist layer.

9. The printed circuit board of claim 1, further comprising:
a first via located in a first via hole within the first insulating layer and connected to the first wiring layer,
wherein the depth of the first part is substantially equal to a first thickness of the first wiring layer, and
the depth of the second part is less than a second thickness of the first via.

10. The printed circuit board of claim 9, wherein
the depth of the third part is substantially equal to a third thickness of the first solder resist layer.

11. A manufacturing method of a printed circuit board, comprising:
forming a first wiring layer and a first sacrificial layer;
stacking a first insulating layer burying the first wiring layer and the first sacrificial layer on the first wiring layer and the first sacrificial layer;
forming a first via hole overlapping a first wiring layer in the first insulating layer;
forming a first via in the first via hole of the first insulating layer;
forming a preliminary cavity by removing the first sacrificial layer by a first etching; and
removing an edge portion of a bottom portion of the preliminary cavity by a second etching to form a cavity in which a depth of a central portion is less than a depth of an edge portion along a height direction.

12. The manufacturing method of claim 11, further comprising:
forming a solder resist layer having an opening exposing the preliminary cavity on the first insulating layer.

13. The manufacturing method of claim 12, wherein
the cavity includes a first part in the portion of the first insulating layer, a second part in the edge portion of the cavity, and a third part in the first solder resist layer, and
through the second etching, a side wall of the first part and a side wall of the second part are aligned with each other along the height direction.

14. The manufacturing method of claim 13, wherein
a width of the first part, a width of the second part, and a width of the third part are different from each other along a plane direction perpendicular to the height direction.

15. The manufacturing method of claim 14, wherein
the width of the second part is less than the width of the first part and the third width of the third part.

16. The manufacturing method of claim 15, wherein
the width of the third part is greater than the width of the first part.

17. The manufacturing method of claim 16, wherein
the depth of the first part is substantially equal to a first thickness of the first wiring layer, and
the depth of the second part is less than a second thickness of the first via.

18. The manufacturing method of claim 17, wherein
the depth of the third part is substantially equal to a third thickness of the first solder resist layer.

19. The manufacturing method of claim 11, wherein
the depth of the first part is substantially equal to a first thickness of the first wiring layer, and
the depth of the second part is less than a second thickness of the first via.

20. The manufacturing method of claim 19, wherein
the depth of the third part is substantially equal to a third thickness of the first solder resist layer.
